(19) United States
(12) Patent Application Publication
(10) Pub. No.: US 2025/0308988 A1
(43) Pub. Date: Oct. 2, 2025

(54) METHOD FOR PROTECTING GRAPHENE LAYER DURING METAL ETCHING

(71) Applicant: Tokyo Electron Limited, Tokyo (JP)

(72) Inventors: Christopher Catano, Albany, NY (US); Na Young Bae, Leuven (BE); Jeffrey Shearer, Albany, NY (US); Brandon Byrns, Albany, NY (US); Joshua Larose, Albany, NY (US); Nicholas Joy, Albany, NY (US); David L O’Meara, Albany, NY (US)

(21) Appl. No.: 18/620,129

(22) Filed: Mar. 28, 2024

(51) Int. Cl. H01L 21/768; H01L 21/033; H01L 21/3205; H01L 21/3213

(52) U.S. Cl. CPC H01L 21/76834; H01L 21/0332; H01L 21/32051; H01L 21/32136; H01L 21/32139; H01L 21/76831; H01L 21/76837; H01L 21/76885

(57) ABSTRACT

A method for making a semiconductor device can include providing an intermediate structure comprising a substrate, a metal layer, a graphene layer, and a mask layer, where the metal layer is over the substrate, where the graphene layer is over the metal layer, where the mask layer is over the graphene layer, and where the mask layer and the graphene layer are patterned and etched with recesses opening to a top surface of the metal layer such that sidewalls of the graphene layer are exposed in the recesses, conformally depositing a barrier layer over the intermediate structure such that the barrier layer covers the sidewalls of the graphene layer in the recesses, and anisotropically etching the metal layer via the recesses.

### TECHNICAL FIELD

The present disclosure relates generally to methods for manufacturing semiconductor devices, and more particularly, protecting a graphene layer during metal etching in a method for manufacturing semiconductor devices.

### BACKGROUND

An integrated circuit contains various semiconductor devices and a plurality of conducting metal paths that provide electrical power to the semiconductor devices and allow the semiconductor devices to share and exchange information. Within the integrated circuit, metal layers are stacked on top of one another using intermetal and interlayer dielectric layers (ILDs) that insulate the metal layers from each other.

Normally, each metal layer must form an electrical contact to at least one additional metal layer. Such electrical contact is achieved by etching a feature (i.e., a via) in the interlayer dielectric layer that separates the metal layers, and filling the resulting via with a metal to create an interconnect. A “via” normally refers to any feature such as a hole, line, or other similar feature formed within a dielectric layer and filled with a metal plug that provides an electrical connection through the dielectric layer to a conductive layer underlying the dielectric layer. Similarly, metal layers connecting two or more vias are normally referred to as “trenches.”

An increase in device performance is normally accompanied by a decrease in device area or an increase in device density. An increase in device density requires a decrease in the dimensions of the vias and trenches used to form interconnects. Copper (Cu) metal is commonly used in multilayer metallization schemes for manufacturing advanced integrated circuits. Problems associated with the use of Cu metal in increasingly smaller features in a substrate will require replacing the Cu metal with one or more low-resistivity metals in those features.

As device feature size continues to scale down, minimizing the device contact resistance has become a significant challenge especially for tight metal pitch. To mitigate the device contact resistance at joins of interconnects for conductors, use of a graphene layer at such joins of interconnect for conductors can minimize electromigration as well as reduce the total line resistance, especially for copper-alternatives used as conductors in vias and trenches. However, graphene is generally sensitive to processing conditions typically used for etching certain metals and is prone to damage from conventional patterning integration.

### SUMMARY

In accordance with an embodiment of the present disclosure, a method for making a semiconductor device can include: providing an intermediate structure comprising a substrate, a metal layer, a graphene layer, and a mask layer, where the metal layer is over the substrate, where the graphene layer is over the metal layer, where the mask layer is over the graphene layer, and where the mask layer and the graphene layer are patterned and etched with recesses opening to a top surface of the metal layer such that sidewalls of the graphene layer are exposed in the recesses; conformally depositing a barrier layer over the intermediate structure such that the barrier layer covers the sidewalls of the graphene layer in the recesses; and anisotropically etching the metal layer via the recesses.

In accordance with an embodiment of the present disclosure, a method for making a semiconductor device can include: providing an intermediate structure comprising a substrate, a metal layer, a graphene layer, and a mask layer, where the metal layer is over the substrate, where the graphene layer is over the metal layer, where the mask layer is over the graphene layer, and where the mask layer and the graphene layer are patterned and etched with recesses opening to a top surface of the metal layer such that sidewalls of the graphene layer are exposed in the recesses, where the metal layer contains one of or any combination of ruthenium, molybdenum, and tungsten; conformally depositing a barrier layer over the intermediate structure such that the barrier layer covers the sidewalls of the graphene layer in the recesses; and anisotropically etching the metal layer via the recesses, where an etching gas for the anisotropic etching contains oxygen, and where the barrier layer includes a barrier material that etches slower than the metal layer in the anisotropic etching using the etching gas containing oxygen.

In accordance with an embodiment of the present disclosure, a method for making a semiconductor device can include: forming a metal layer over a substrate, where the metal layer contains one of or any combination of ruthenium, molybdenum, and tungsten; forming a first graphene layer over the metal layer; forming a first mask layer over the metal layer; forming a second mask layer over the first mask layer; patterning and etching the second mask layer to form recesses in the second mask layer; patterning and etching the first mask layer to extend the recesses through the first mask layer; patterning and etching the first graphene layer to extend the recesses through the first graphene layer to form an intermediate structure; conformally depositing a barrier layer over the intermediate structure such that the barrier layer covers sidewalls of the first graphene layer in the recesses; anisotropically etching the metal layer to extend the recesses in the metal layer, where an etching gas for the anisotropic etching contains oxygen, where the barrier layer includes a barrier material such the metal layer selectively etched relative to the barrier layer in the anisotropic etching using the etching gas containing oxygen, and where the sidewalls of the first graphene layer remain covered by the barrier layer during the etching of the metal layer; and sequentially repeating the depositing of the barrier layer and the etching of the metal layer until the recesses open to the substrate.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a cross-section view illustrating an intermediate structure during a method of making a semiconductor device according to an embodiment of the present disclosure;

FIG. 2 is a cross-section view illustrating an intermediate structure during a method of making a semiconductor device according to an embodiment of the present disclosure;

FIG. 3 is a cross-section view illustrating an intermediate structure during a method of making a semiconductor device according to an embodiment of the present disclosure;

FIG. 4 is a cross-section view illustrating an intermediate structure during a method of making a semiconductor device according to an embodiment of the present disclosure;

FIG. 5 is a cross-section view illustrating an intermediate structure during a method of making a semiconductor device according to an embodiment of the present disclosure;

FIG. 6 is a cross-section view illustrating an intermediate structure during a method of making a semiconductor device according to an embodiment of the present disclosure;

FIG. 7 is a cross-section view illustrating an intermediate structure during a method of making a semiconductor device according to an embodiment of the present disclosure;

FIG. 8 is a cross-section view illustrating an intermediate structure during a method of making a semiconductor device according to an embodiment of the present disclosure;

FIG. 9 is a cross-section view illustrating an intermediate structure during a method of making a semiconductor device according to an embodiment of the present disclosure;

FIG. 10 is a cross-section view illustrating an intermediate structure during a method of making a semiconductor device according to an embodiment of the present disclosure;

FIG. 11 illustrates a flow chart implementing the protecting of a graphene layer while etching a metal layer in accordance with an embodiment of the present disclosure;

FIG. 12 illustrates a flow chart implementing the protecting of a graphene layer while etching a metal layer in accordance with an embodiment of the present disclosure; and

FIG. 13 illustrates a flow chart implementing the protecting of a graphene layer while etching a metal layer in accordance with an embodiment of the present disclosure.

### DETAILED DESCRIPTION OF ILLUSTRATIVE EMBODIMENTS

Referring now to the drawings, in which like reference numbers can be used herein to designate like or similar elements throughout the various views, illustrative and example embodiments are shown and described. The figures are not drawn to scale, and in some instances the drawings are exaggerated or simplified in places for illustrative purposes. One of ordinary skill in the art can appreciate many possible applications and variations for other embodiments based on the following illustrative and example embodiments provided in the present disclosure. Some example embodiments of the present disclosure are described below. Other embodiments can also be understood from the entirety of the specification as well as the claims filed herein.

In the present disclosure, terms such as “first”, “second”, and the like, may be used to describe various components, but the components are not necessarily limited by such terms, for example, regarding order, sequence, importance, or number of such components possible in an embodiment. Such terms can be used merely for the purpose of distinguishing one component from other components in a given embodiment or group of embodiments. For example, a first component may be referred to as a second component, and similarly, a second component may also be referred to as a first component without departing from the scope of rights according to the present disclosure.

The minimum dimension of patterned features can be shrunk periodically to roughly double the component density at each successive technology node, thereby reducing the cost per function. Innovations in patterning, such as immersion deep ultraviolet (i-DUV) lithography, multiple patterning and 13.5 nm wavelength extreme ultraviolet (EUV) optical systems have brought some critical dimensions down a scale close to ten nanometers. This squeezes the margin for pattern misalignment and puts pressure on process integration to prevent electrical opens and shorts in middle-of-line (MOL) and back-end-of-line (BEOL) interconnect elements.

The conventional use of copper as conductive material for vias and/or trenches becomes challenging as device feature sizes continue to scale down because copper requires barrier layers and liners to prevent migration of the copper. As feature sizes for MOL and BEOL interconnect elements continue to scale down, copper-alternatives that do not require barrier layers and liners are being investigated and implemented. However, such copper-alternatives present new issues and problems to tackle, such as minimizing the device contact resistance at joining interfaces of conducting structures, especially for tight metal pitches, and line resistance. Some example metal materials that can be used as copper alternatives are ruthenium (Ru), cobalt (Co), molybdenum (Mo), tungsten (W), and niobium (Nb), for example. To mitigate the device contact resistance at joins of interconnects for conductors, use of a graphene layer at such joins of interconnect for conductors can minimize electromigration as well as reduce the total line resistance, especially for copper-alternatives used as conductors in vias and trenches. Also, graphene can be formed around part of or all of (encapsulating) such patterned metal features to reduce total line resistance in some cases. Thus, both contact resistance and line resistance can be improved using a graphene layer as a cap between join interfaces and using graphene layer(s) wrapped on one, some, or all sides of the metal line covering all of or most of the line.

An issue with graphene is that graphene is very sensitive and can be damaged very easily, especially during etching processes in which the etch chemistry contains oxygen because such etching is not selective against etching graphene and graphene can be etched very quickly and easily when the etch chemistry contains oxygen. And for some of the copper-alternative metals, such as ruthenium, molybdenum, and tungsten, a reactive ion etching (RIE), for example, for etching such metals can use or typically use an etch chemistry that contains oxygen an etch gas (e.g., as part of an etch gas mixture) flowed into a plasma chamber or an etching chamber. In some cases, the graphene can etch much faster (large differences) than the metal layer.

Lateral etching and/or damage to the graphene layer can create issues, such as delamination and/or degradation of a structural integrity of the hard mask structure sitting on the graphene layer (which can be unacceptable for downstream processing), non-ideal electrical properties, and stochastics that can drive reliability issues. Thus, there is a need for methods of making semiconductor devices that implement graphene layers in combination with metals that are typically or preferably etched using a flow of oxygen.

In some embodiments of the present disclosure, a method of making a semiconductor device includes protecting a graphene layer during the etching of a metal layer. Graphene can be easily etched when the etch chemistry includes oxygen. For certain metals, oxygen is typically included in the etch chemistry for etching such metals. Thus, to protect the graphene layer during the etching of a metal using an etch chemistry that contains oxygen, a barrier layer can be formed over exposed portions of the graphene. A material of such barrier layer can be selected so that the etching of the metal using an etch chemistry containing oxygen can be selective to etching the metal stronger (more, faster) than the barrier layer.

FIGS. 1-10 are cross-section views illustrating intermediate structures during a method of making a semiconductor device according to an embodiment of the present disclosure. For simplification and illustration purposes, FIGS. 1-10 are merely showing some portions of a substrate for a semiconductor device as intermediate structures that can be relevant to a method of making a semiconductor device according to an embodiment of the present disclosure. For example, in FIGS. 1-10, to simplify the drawings, as can be readily understood by one of ordinary skill in the pertinent art, additional layers and structures of a substrate for a semiconductor device made before, under, below, or adjacent to the intermediate structures shown in the drawings are omitted, which can include any structures, types, and semiconductor devices, such as additional interconnects, additional vias, additional trenches, additional interlayer dielectric layers, additional intermetal dielectric layers, additional backend-of-line (BEOL) stage(s) or level(s), frontend-of-line (FEOL) stages or levels, transistors, diodes, capacitors, resistors, inductors, integrated circuits, memory cells, logic, processor portions, digital devices, analog devices, semiconductor wafer, silicon-on-insulator wafer, or combinations thereof, for example. Also in FIGS. 1-10, to simplify the drawings, as can be readily understood by one of ordinary skill in the pertinent art, additional layers and structures of a substrate for a semiconductor device made after, over, above, or adjacent to the intermediate structures shown in the drawings are omitted, which can include any structures, types, and semiconductor devices, such as additional interconnects, additional vias, additional trenches, additional interlayer dielectric layers, additional intermetal dielectric layers, additional backend-of-line (BEOL) stage(s) or level(s), passivation layers, contact pads, local interconnects, global interconnects, wire bonding, packaging, or combinations thereof, for example. Furthermore, in an actual completed semiconductor device cross-section, the intermediate structures, which are illustrated and represented in the drawings of the present disclosure in a simplified manner as having squared edges and/or linear shapes, can be actually more rounded, more curved shaped, and less linear shaped, and can be perhaps even difficult to visually see even in an image taken with a scanning electron microscope (SEM) or a transmission electron microscope (TEM) due the extremely small size, thickness, and scale of some layers and resulting features (e.g., some on the scale of atoms to less than 5 nanometers in size).

Referring to FIG. 1, a first intermediate structure 51 can include a substrate 20, a metal layer 22, a graphene layer 26, a first mask layer 31, and a second mask layer 32, according to an example embodiment of the present disclosure. The metal layer 22 can be on or over the substrate 20. The graphene layer 26 can be on or over the metal layer 22. The second mask layer 32 can be on or over the graphene layer 26. The first mask layer 31 can be on or over the second mask layer 32. In FIG. 1, the first intermediate structure 51 can be after patterning and etching the first mask layer 31 to from a pattern of recesses 40 in the first mask layer 31. A goal of the example method illustrated in FIGS. 1-10 can be transferring the pattern formed in the first mask layer 31 to the metal layer 22 by extending the recesses 40 from the first mask layer 31 into or through the metal layer 22 while retaining and/or additionally forming enough graphene of the graphene layer 26 on the metal layer 22 so that the graphene can perform functions of minimizing electromigration of the metal layer and/or reducing a total line resistance when connecting patterned features of the metal layer to other conducting structures (e.g., other patterned metal layers, vias, or trenches).

A metal layer 22 can be any suitable conducting material for forming a middle-of-line (MOL) and/or back-end-of-the-line (BEOL) conducting structure, such as a via and a trench, for example. In some embodiments, the metal layer 22 can contain ruthenium (Ru), molybdenum (Mo), tungsten (W), alloys thereof, or any combination thereof, for example. In some embodiments, a metal layer 22 can be any suitable conducting material that can be or that is typically etched using an etch chemistry that contains oxygen (e.g., oxygen included in an gas mixture flowed into a plasma or etching chamber). In some embodiments, a metal layer 22 can be formed by sputtering, physical vapor deposition (PVD), chemical vapor deposition (CVD), plasma-enhanced CVD (PECVD), atomic layer deposition (ALD), plasma-enhanced ALD (PEALD), or any combination thereof, for example. Even though the metal layer 22 is illustrated and represented in the drawings as a single layer of one material, in some embodiments, the metal layer 22 can be a single layer of one material, a single layer of an alloy or mix of multiple materials, multiple layers of one material, multiple layers of a same alloy or mix of multiple materials, or multiple layers of different materials or alloy(s) of materials, for example.

In some embodiments, a graphene layer 26 can be formed using a suitable deposition process such as a chemical vapor deposition (CVD), plasma enhanced CVD (PECVD), atomic layer deposition (ALD), or plasma enhanced ALD (PEALD) process with an appropriate graphene precursor. In some embodiments, a graphene layer 26 can be formed using a layer transfer method.

In some embodiments, a graphene layer 26 can be formed by chemical vapor deposition (CVD) for growing graphene. A gaseous precursor containing carbon can be introduced into a high-temperature reactor or chamber along with the wafer. The carbon atoms from the precursor can then react on the surface of the metal layer 22 to thereby form an initial sheet of graphene. A CVD process can be continued to build up, grow, or deposit additional sheets of graphene to increase a thickness of the resulting graphene layer. The temperature and gas composition can be used to control a quality and thickness of the graphene. In some embodiments, PECVD can be used as a variation of CVD to enhance the deposition process. Plasma can provide additional energy to facilitate the growth of high-quality graphene sheets.

In some embodiments, a graphene layer 26 can be formed by liquid phase exfoliation, which can include breaking down graphite into individual graphene sheets using a solvent and then dispersing the graphene over the metal layer 22. Liquid phase exfoliation can be a scalable and relatively low-cost method of depositing graphene, but the results can be less controllable for layer uniformity compared to CVD.

In some embodiments, silicon carbide (SiC) can be converted to graphene by annealing the silicon carbide at high temperature to sublimate silicon atoms to leave behind a graphene layer. However, this conversion process can consume significant thermal budget.

In some embodiments, graphene can be epitaxially grown onto a surface having a similar crystal structure, but this process also can require high temperature and specific material properties for the metal layer 22 onto which the graphene is grown.

In some embodiments, a selective graphene deposition can be performed using a suitable selective deposition process, such as a chemical vapor deposition (CVD), plasma enhanced CVD (PECVD), atomic layer deposition (ALD), or plasma enhanced ALD (PEALD) process with an appropriate graphene precursor.

In some embodiments, the formation of the graphene can be performed using a vapor deposition process at a temperature in a range of 40° C. to 150° C. The graphene can have a decomposition temperature range of 200° C. to 350° C.

Prior to performing graphene deposition, graphene growth, or selective graphene deposition, an optional pretreatment can be performed to remove any surface oxide so that a surface of the metal layer 22 becomes accessible for subsequent process steps. In various embodiments, the optional pretreatment can be a wet process. In one example, an alcohol solution can be applied at room temperature for a predetermined time. The alcohol solution can include one or more alcohols or, alternatively, the alcohol solution can include one or more alcohols and a non-oxidizing solvent. The alcohol solution can contain any alcohol with a chemical formula R—OH. One class of alcohols is primary alcohols, of which methanol and ethanol are the simplest members. Another class of alcohols is secondary alcohols, for example isopropyl alcohol (IPA). In certain embodiments, the optional pretreatment can also include an operation or step to remove moisture from the intermediate structure (e.g., substrate and/or the metal layer). The removal of moisture can be performed, for example, by a thermal treatment under an inert gas flow. In certain embodiments, the optional pretreatment can include a dry process using one or more reducing gases with or without a plasma.

The choice of process(es) for forming graphene sheets for a graphene layer 26 can depend on factors such as a desired graphene quality, scalability, and specific requirements of a given semiconductor application. Each process of forming graphene has its advantages and challenges, and researchers are continually exploring new techniques to improve the deposition processes for graphene.

In various embodiments, a graphene layer 26 can include a single graphene sheet or several graphene sheets, and thus have a thickness of one to several atomic layers (e.g., less than 1 nm). The material properties of graphene such as superior electrical conductivity can make graphene an attractive alternative to form a capping layer compared to conventional metals. Further, the use of graphene can advantageously enable a very thin capping layer on the metal layer 22. In some embodiments, a graphene layer 26 can include several graphene sheets to form a thicker graphene layer with a thickness in a range of 5 nm to 10 nm), for example. Thus, in various embodiments, a graphene layer can have a thickness in a range of less than 1 nm (e.g., one sheet of graphene) to 10 nm (multiple sheets of graphene), for example.

In some embodiments, prior to subsequent deposition steps after forming a graphene layer, an optional post-graphene treatment, such as annealing, can be performed to remove impurities and/or improve a quality and structure of the deposited/grown graphene.

A hard mask structure over the graphene layer can include a first mask layer 31 and a second mask layer 32. In some embodiments, a first mask layer 31 can contain any suitable mask material, such as an oxide containing material. In some embodiments, a second mask layer 32 can contain silicon nitride (SiN), silicon carbide (SiC), silicon oxynitride (SiON), silicon oxycarbide nitride (SiOCN), silicon carbonitride (SiCN), aluminum nitride (AlN), boron nitride (BN), tantalum nitride (TaN), zirconium nitride (ZrN), or any combination thereof, for example. The first mask layer 31 and the second mask layer 32 can be formed using a suitable deposition process such as a chemical vapor deposition (CVD), plasma enhanced CVD (PECVD), atomic layer deposition (ALD), or plasma enhanced ALD (PEALD), for example. Even though each of the first mask layer 31 and the second mask layer 32 is illustrated and represented in the drawings as a single layer of one material, in some embodiments, each of the first mask layer 31 and/or the second mask layer 32 can be a single layer of one material, a single layer of an alloy or mix of multiple materials, multiple layers of one material, multiple layers of a same alloy or mix of multiple materials, or multiple layers of different materials or alloy(s) of materials, for example. In some embodiments, the stack order of the first mask layer 31 and the second mask layer 32 can be reversed. In some embodiments, the hard mask structure over the graphene layer 26 can include less or more mask layers relative to the example embodiment illustrated in the drawings.

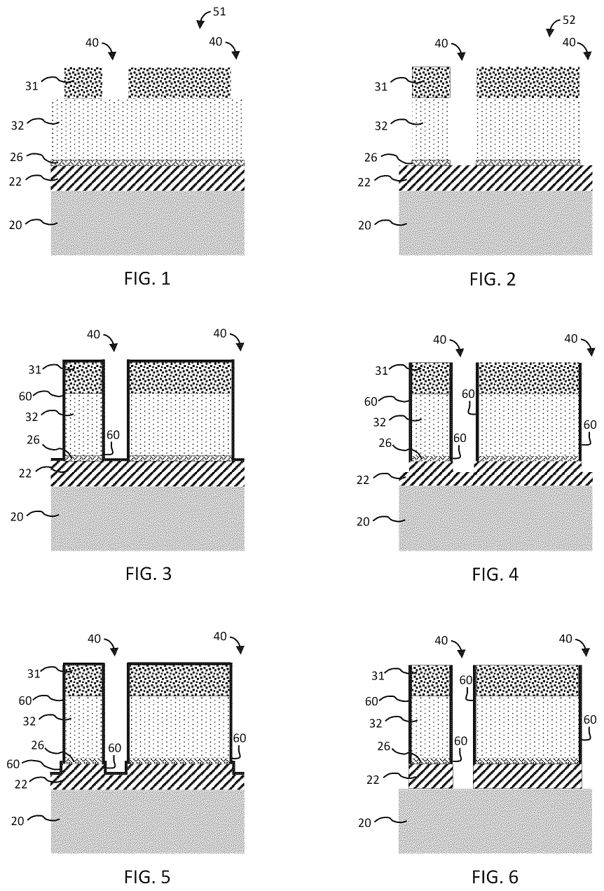

Referring to FIG. 2, the recesses 40 can be extended through the second mask layer 32 and the graphene layer 26 by patterning and etching the second mask layer 32 and the graphene layer 26, together or separately. As illustrated in a second intermediate structure 52 shown in FIG. 2, the recesses 40 can open to a top surface of the metal layer 22. In some embodiments, the etching of the second mask layer 32 and the graphene layer 26 can be selective to etching the second mask layer 32 and/or the graphene layer 26 stronger then etching the underlying metal layer 22, such that the metal layer 22 may act as an etch stop for arriving at the second intermediate structure 52 of FIG. 2.

In some embodiments, the etching of the second mask layer 32 and/or the graphene layer 26 can be timed. In some embodiments, the etching of the second mask layer 32 and the graphene layer 26 can be an anisotropic etch, such as RIE. There can be one or more other intermediate structures formed between the formation of the first intermediate structure 51 shown in FIG. 1 and the second intermediate structure 52 shown in FIG. 2, as can be apparent to one of ordinary skill in the art to which the present disclosure pertains. For example, because plasma and/or etch conditions for etching the second mask layer 32 efficiently with directionality can easily damage the graphene layer 26 when the etch front reaches the graphene layer, the etching of the second mask layer 32 may need to be terminated before etching through an entire thickness of the second mask layer 32. And then, one or more less aggressive etches that can be less damaging to the graphene layer 26 can be performed for a remainder of the thickness of the second mask layer 32 and/or for the graphene layer 26, for example. In some embodiments, part or all of the etching of the second mask layer 32 and/or for the graphene layer 26 can be a timed etch. In some embodiments, etch products can be monitored in real-time by appropriate chemical analysis tools (e.g., optical emission spectroscopy), so that a detection of chemical elements from the graphene layer 26 and/or the metal layer 22 indicates that the recesses 40 reach a level of the graphene layer 26 and/or the metal layer 22. The second mask layer 32 and the graphene layer 26 can be patterned and etched with recesses 40 opening to a top surface of the metal layer 22 such that sidewalls of the graphene layer 26 are exposed in the recesses 40.

In the second intermediate structure 52 illustrated in FIG. 2, sidewalls of the graphene layer 26 can be exposed in the recesses 40. If the etching of the metal layer 22 were to proceed on the second intermediate structure 52 of FIG. 2 using an etch gas containing oxygen, even if the etch is performed anisotropically such as a reactive ion etching with ions bombarding bottoms of the recesses 40 mostly perpendicular to a top surface of the wafer, the graphene layer 26 would most likely be laterally etched. Such lateral etching of the graphene layer 26 would result in a decreased width of the patterned features of the graphene layer 26 (i.e., undercutting of the graphene layer 26), which is not desirable in most process flows. In some process flows, it may be most beneficial to retain the width of the patterned features of the graphene layer 26 so that the graphene layer 26 is still sufficiently covering the metal layer 22 (e.g., so that the graphene can sufficiently or better perform the functions for which it was placed there, i.e., minimizing electromigration of the metal layer 22 and/or reducing a total line resistance for conducting paths including the metal layer 22). Accordingly, an embodiment of the present disclosure can provide a process flow in which the graphene layer 26 is protected during the etching of the metal layer 22.

Referring to FIG. 3, a barrier layer 60 can be conformally deposited over the second intermediate structure 52 of FIG. 2. The barrier layer 60 can be formed using chemical vapor deposition (CVD), plasma-enhanced CVD (PECVD), atomic layer deposition (ALD), plasma-enhanced ALD (PEALD), or any combination thereof, for example. In some embodiments, the barrier layer 60 can be silicon nitride (SiN), for example. In some embodiments, a nitride film can be preferred for the barrier layer 60, but an oxide film can also work for the barrier layer 60. If an oxide film is used for the barrier layer 60, the graphene layer 26 can be undercut slightly (laterally etched) but after a first few monolayers of deposition, the interaction with graphene can be diminished, which can make an oxide film feasible for some embodiments. Accordingly, in some embodiments, a barrier layer 60 can contain titanium dioxide (TiO₂), tungsten oxide (WO₃), aluminum oxide (Al₂O₃), silicon dioxide (SiO₂), zirconium oxide (ZrO₂), hafnium oxide (HfO₂), niobium pentoxide (NbO₅), vanadium pentoxide (V₂O₅), yttrium oxide (Y₂O₃), silicon nitride (SiN), silicon carbide (SiC), silicon oxynitride (SiON), silicon oxycarbide nitride (SiOCN), silicon carbonitride (SiCN), aluminum nitride (AlN), boron nitride (BN), tantalum nitride (TaN), zirconium nitride (ZrN), or any combination thereof, for example.

As illustrated in FIG. 3, the barrier layer 60 can cover and protect the previously exposed sidewalls of the graphene layer 26. Because the graphene layer 26 can be extremely thin (e.g., less than 10 nm) in some embodiments, a non-conformal or partially conformal deposition of the barrier layer 60 may be sufficient to cover the exposed sidewalls or portions of the graphene layer 26. Hence, the barrier layer 60 can be formed using sputtering or physical vapor deposition (PVD) in some embodiments. In many embodiments for which the dimensions of the patterned recesses have relatively small widths (e.g., 5-20 nm) and relatively long depths (e.g., 10-40 nm) (e.g., high aspect ratio), ALD can be a preferred process for forming the barrier layer 60.

Referring to FIG. 4, the metal layer 22 can be etched to further transfer the pattern from the hard mask structure and to extend the recesses 40 into the metal layer 22. The etching of the metal layer 22 can be an anisotropic etch, such as reactive ion etching (RIE) with ions bombarding the bottoms of the recesses 40 in a direction perpendicular to a top surface of the substrate 20. Based on the material of the metal layer 22, an etch chemistry, or a flow of gas into the chamber for the RIE, containing oxygen can be used to etch the metal layer. The presence of the barrier layer 60 covering and shielding the graphene layer 26 can hinder or prevent the graphene layer 26 from being laterally etched during the etching of the metal layer 22.

In some embodiments, depending on a thickness of the metal layer 22 and a thickness of the barrier layer 60, as well as the etch selectivity of the metal layer 22 relative to the barrier layer 60, the etching of the metal layer 22 to open the recesses 40 to the underlying substrate 20 can be done in one operation. In some embodiments, again depending on a thickness of the metal layer 22, a thickness of the barrier layer 60, and the etch selectivity of the metal layer 22 relative to the barrier layer 60, the etching of the metal layer 22 may be stopped such that the recesses 40 extends only partially through the metal layer 22, before exposing the graphene layer 26 (e.g., before the barrier layer 60 is etched away too much), as illustrated in FIG. 4 for example.

Referring to FIGS. 5 and 6, the operations of the depositing the barrier layer 60 and etching the metal layer 22 can be sequentially repeated until the recesses 40 in the metal layer 22 open to the substrate 20 and while the graphene layer 26 remains covered by the barrier layer 60 during the etching of the metal layer 22. The drawings in FIGS. 4-6 are simplifications illustrating one repeat of the depositing of the barrier layer 60 and etching of the metal layer 22, but in some embodiments the depositing of the barrier layer 60 and etching of the metal layer 22 can be repeated or cycled any number of times. The operations resulting in the intermediate structures of illustrated in FIGS. 5 and 6 can be repeats of the operations described above relating to FIGS. 3 and 4, respectively.

Although the barrier layer 60 in FIG. 5 is shown as a single uniform layer of a single material (for simplification of illustration), the actual barrier layer illustrated in FIG. 5 can include new portions of the barrier layer combined with older remaining portions of the barrier layer (after prior etching(s) of the metal layer 22) from prior depositions of the barrier layer, which can become multiple laminates of the prior barrier layers at some places as the number of cycles increases, for example. Thus, the barrier layer 60 can be a composite of new barrier layer portions formed on newly exposed surfaces in the recesses 40 (e.g., after an immediately prior vertical anisotropic etching operation), combined with one or more prior barrier layers formed during one or more prior depositions of the barrier layer at different times from different operations.

In some embodiments, part or all of the etching of the metal layer 22 can be a timed etch. In some embodiments, etch products can be monitored in real-time by appropriate chemical analysis tools (e.g., optical emission spectroscopy), so that a detection of chemical elements from the substrate 20 indicates that the recesses 40 reach to a level of the substrate 20.

In some embodiments, the etching of the metal layer 22 can over etch (i.e., not stopping precisely at the top surface of the substrate 20) to begin forming the recesses in the substrate 20. In an actual intermediate structure at this stage, due to some inherent non-uniformity across the wafer or among some portions of the pattern or among some portions of the wafer, some recesses 40 can barely open to the substrate 20, some recesses 40 can sufficiently open to the substrate 20 and stop short of forming recesses into the substrate 20 (e.g., etching stopping on the top surface of the substrate 20), and some recesses can over etch to begin forming corresponding recesses in the underlying substrate. The amount and extent for which the underlying substrate 20 is etched while sufficiently opening the recesses of the metal layer 22 to the substrate can depend on the shape of the etch front at the bottom of the recesses 40. In some embodiments, the etch chemistry for etching the metal layer 22 can be selective to etch the metal layer 22 stronger (more, faster) than the substrate 20 and/or an etch stop layer (not shown) located between the metal layer and the substrate, for example.

After the anisotropic etch of the metal layer 22, portions of the barrier layer 60 can remain on at least part of sidewalls of the recesses 40, as illustrated in FIG. 6 for example. In an actual intermediate structure of the simplified intermediate structure illustrated in FIG. 6, the etching of the metal layer 22 can form a pointed shape or rounded shape at the bottom of the recesses 40, and remaining portions of the barrier layer 60 can be pitted, irregular shaped, varying in thickness, tapering in thickness (thinner towards the bottom/top of the recesses), or any combination thereof, for example.

As illustrated in FIG. 6, the widths of the patterned features of the graphene layer 26 can remain constant during the etching of the metal layer 22 because the barrier layer 60 can protect the graphene layer from lateral etching during the etching of the metal layer. By cycling or repeating the depositing of the barrier layer 60 as needed, and/or depending on the initial thickness of the barrier layer 60 and/or subsequent thickness(es) of the barrier layer deposition(s) (e.g., relative to the thickness of the metal layer 22 to be etched), the graphene layer 26 can remain covered by the barrier layer 60 during part or all of the etching of the metal layer 22.

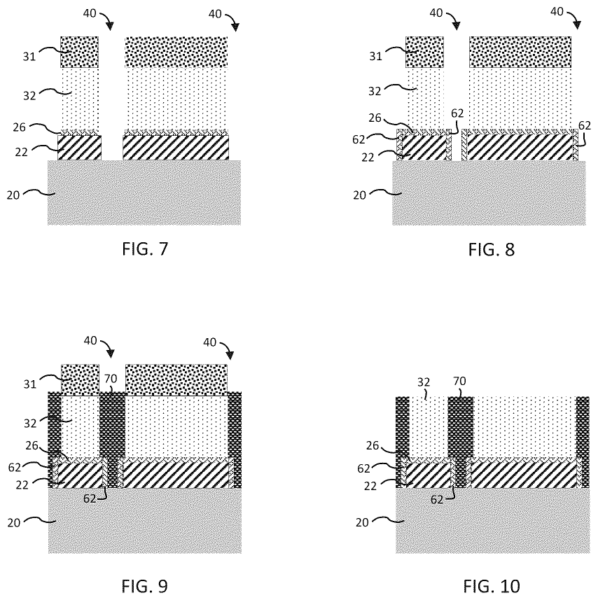

Referring to FIG. 7, in some embodiments, part of or most of the barrier layer can be removed after the recesses 40 are open to the substrate 20. In some embodiments, most of or all of the remaining portions of the barrier layer can be removed, as illustrated in FIG. 7. The remaining portions of the barrier layer can be removed by wet etching and/or dry etching, isotropically and/or anisotropically, using an etch chemistry that can remove the barrier layer with little or no damage or etching to the graphene layer 26. Alternatively or in addition, the intermediate structure can be cleaned using a hydrofluoric acid (HF) or diluted hydrofluoric acid (DHF), for example. In some embodiments, a step of removing the barrier layer can be omitted (e.g., because only portions of the barrier layer remain). In some embodiments, part of the barrier layer can remain in the recesses 40 during some subsequent operations.

Referring to FIG. 8, in some embodiments, it may be desirable to cover exposed portions of the metal layer 22 with another graphene layer 62 by performing another operation of forming graphene (e.g., on the intermediate structure of FIG. 7 to result in the intermediate structure of FIG. 8). This second formation of another graphene layer 62 can be performed using a same process as used to form the graphene layer 26 (formed prior to the first intermediate structure 51 of FIG. 1), or using any suitable process such as one of the processes previously described relating to FIG. 1, for example. This second graphene layer 62 can be a same or different thickness as the first graphene layer 26 formed for the first intermediate structure 51 shown in FIG. 1.

Referring to FIG. 9, in some embodiments, a dielectric layer 70 can be formed between the patterned features of the metal layer 22. The dielectric layer 70 can contain one or more low-k dielectric materials, such as silicon dioxide (SiO₂), organosilicate glass (OSG), fluorinated silicon glass or fluorosilicate glass (FSG), low-k spin-on dielectric (SOD), organic low-k materials, or any combinations thereof, for example. The thickness of the dielectric layer 70 can vary for different embodiments. In some embodiments, the step of forming a second graphene layer 62 (as illustrated in FIG. 8 as an example) can be omitted, and accordingly, the dielectric layer 70 can be formed directly on the metal layer 22. In other words, the second graphene layer 62 of FIG. 9 can be omitted in some embodiments.

Referring to FIG. 10, the first mask layer 31 can be removed, such as by etching and/or chemical mechanical polishing (CMP), and optionally followed by a cleaning process to remove impurities, for example, to planarize a top surface of the intermediate structure in preparation for subsequent operations.

Other downstream processes may also run into the same issues of sensitivity and ease of damaging the graphene layer 26, such as during a contact or via etch landing on the graphene layer, and thus should avoid oxygen in the presence of graphene or etching with an etch chemistry containing oxygen on, near, or at the graphene layer.

By implementing an embodiment of the present disclosure, a graphene layer can be incorporated on and/or at least partially around a metal layer, such as ruthenium, which can provide advantages of enabling scaling down sizes (i.e., increasing feature density) of metal of metal interconnects without a need for a barrier layer and/or liner layer (as copper typically requires) while also enabling comparable electrical performance (e.g., compared to copper) at reduced scale. By implementing an embodiment of the present disclosure, lateral etching and/or damage to the graphene layer can be reduced and/or prevented, especially during etching of the metal layer. Accordingly, implementing an embodiment of the present disclosure can provide advantages, such as preventing delamination and/or degradation of a structural integrity of the hard mask structure sitting on the graphene layer, improving electrical properties, and improving stochastics, which can improve reliability.

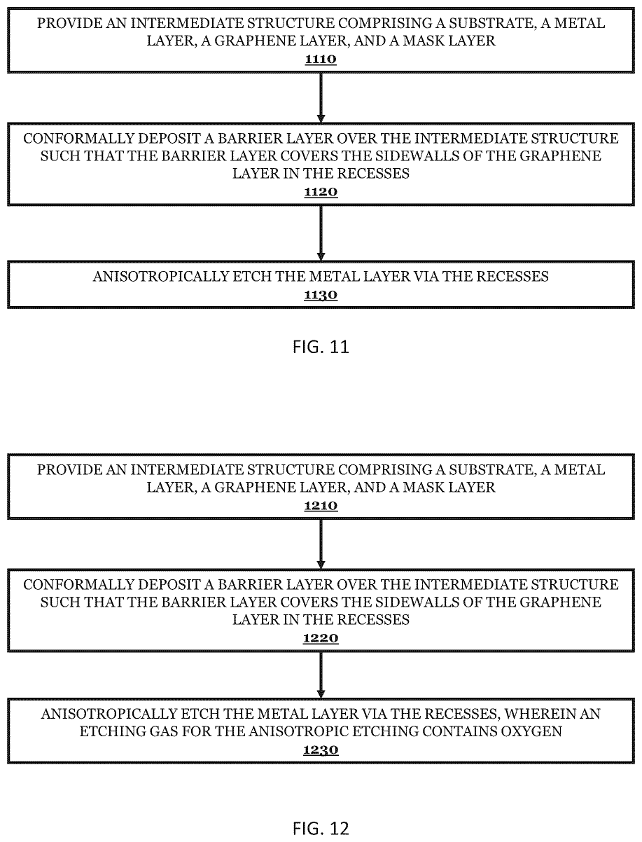

FIG. 11 illustrates a flow chart implementing the protecting of a graphene layer while etching a metal layer in accordance with an embodiment of the present disclosure.

In an embodiment, a method for making a semiconductor device includes providing an intermediate structure comprising a substrate, a metal layer, a graphene layer, and a mask layer, wherein the metal layer is over the substrate, wherein the graphene layer is over the metal layer, wherein the mask layer is over the graphene layer, and wherein the mask layer and the graphene layer are patterned and etched with recesses opening to a top surface of the metal layer such that sidewalls of the graphene layer are exposed in the recesses (box 1110). The method includes conformally depositing a barrier layer over the intermediate structure such that the barrier layer covers the sidewalls of the graphene layer in the recesses (box 1120). The method includes anisotropically etching the metal layer via the recesses (box 1130).

FIG. 12 illustrates a flow chart implementing the protecting of a graphene layer while etching a metal layer in accordance with an embodiment of the present disclosure.

In an embodiment, a method for making a semiconductor device includes providing an intermediate structure comprising a substrate, a metal layer, a graphene layer, and a mask layer, wherein the metal layer is over the substrate, wherein the graphene layer is over the metal layer, wherein the mask layer is over the graphene layer, and wherein the mask layer and the graphene layer are patterned and etched with recesses opening to a top surface of the metal layer such that sidewalls of the graphene layer are exposed in the recesses, wherein the metal layer contains one of or any combination of ruthenium, molybdenum, and tungsten (box 1210). The method includes conformally depositing a barrier layer over the intermediate structure such that the barrier layer covers the sidewalls of the graphene layer in the recesses (box 1220). The method includes anisotropically etching the metal layer via the recesses, wherein an etching gas for the anisotropic etching contains oxygen, and wherein the barrier layer includes a barrier material that etches slower than the metal layer in the anisotropic etching using the etching gas containing oxygen (box 1230).

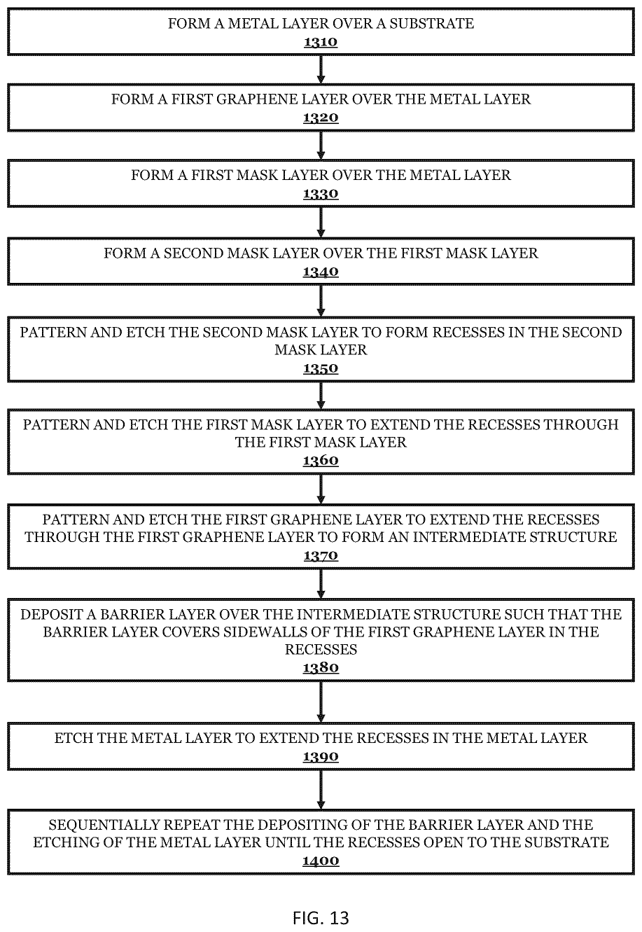

FIG. 13 illustrates a flow chart implementing the protecting of a graphene layer while etching a metal layer in accordance with an embodiment of the present disclosure.

In an embodiment, a method for making a semiconductor device includes forming a metal layer over a substrate, wherein the metal layer contains one of or any combination of ruthenium, molybdenum, and tungsten (box 1310). The method includes forming a first graphene layer over the metal layer (box 1320). The method includes forming a first mask layer over the metal layer (box 1330). The method includes forming a second mask layer over the first mask layer (box 1340). The method includes patterning and etching the second mask layer to form recesses in the second mask layer (box 1350). The method includes patterning and etching the first mask layer to extend the recesses through the first mask layer (box 1360). The method includes patterning and etching the first graphene layer to extend the recesses through the first graphene layer to form an intermediate structure (box 1370). The method includes conformally depositing a barrier layer over the intermediate structure such that the barrier layer covers sidewalls of the first graphene layer in the recesses (box 1380). The method includes anisotropically etching the metal layer to extend the recesses in the metal layer, wherein an etching gas for the anisotropic etching contains oxygen, wherein the barrier layer includes a barrier material such the metal layer selectively etched relative to the barrier layer in the anisotropic etching using the etching gas containing oxygen, and wherein the sidewalls of the first graphene layer remain covered by the barrier layer during the etching of the metal layer (box 1390). The method includes sequentially repeating the depositing of the barrier layer and the etching of the metal layer until the recesses open to the substrate (box 1400).

The embodiments described in FIGS. 11-13 may be implemented as further described using FIGS. 1-10.

More example embodiments of the present disclosure are summarized here. Other embodiments can also be understood from the entirety of the specification as well as the claims filed herein.

Example 1. A method for making a semiconductor device, the method comprising: providing an intermediate structure comprising a substrate, a metal layer, a graphene layer, and a mask layer, where the metal layer is over the substrate, where the graphene layer is over the metal layer, where the mask layer is over the graphene layer, and where the mask layer and the graphene layer are patterned and etched with recesses opening to a top surface of the metal layer such that sidewalls of the graphene layer are exposed in the recesses; conformally depositing a barrier layer over the intermediate structure such that the barrier layer covers the sidewalls of the graphene layer in the recesses; and anisotropically etching the metal layer via the recesses.

Example 2. The method of example 1, further comprising sequentially repeating the depositing of the barrier layer and the etching of the metal layer until the recesses open to the substrate.

Example 3. The method of examples 1 and 2, further comprising removing the barrier layer after the recesses are open to the substrate.

Example 4. The method of examples 1 to 3, further comprising: forming another graphene layer on exposed portions of patterned features of the metal layer; and depositing a dielectric material between the patterned features of the metal layer.

Example 5. The method of example 1, where the metal layer contains ruthenium, where the barrier layer contains silicon and nitrogen, and where an etching gas for the anisotropic etching contains oxygen.

Example 6. The method of examples 1 and 5, where the mask layer comprises a silicon nitride mask layer over a metal oxide mask layer.

Example 7. The method of example 1, where patterned feature widths of the graphene layer remain constant during the etching of the metal layer.

Example 8. The method of example 1, where the graphene layer remains covered by the barrier layer during the etching of the metal layer.

Example 9. The method of example 1, where the graphene layer has a thickness range of 1 nm to 10 nm.

Example 10. The method of example 1, where the barrier layer is silicon nitride, and where the depositing of the barrier layer includes an atomic layer deposition.

Example 11. The method of example 1, where the metal layer contains one of or any combination of ruthenium, molybdenum, and tungsten; where an etching gas for the anisotropic etching contains oxygen; and where the barrier layer includes a barrier material that etches slower than the metal layer in the anisotropic etching using the etching gas containing oxygen.

Example 12. A method for making a semiconductor device, the method comprising: providing an intermediate structure comprising a substrate, a metal layer, a graphene layer, and a mask layer, where the metal layer is over the substrate, where the graphene layer is over the metal layer, where the mask layer is over the graphene layer, and where the mask layer and the graphene layer are patterned and etched with recesses opening to a top surface of the metal layer such that sidewalls of the graphene layer are exposed in the recesses, where the metal layer contains one of or any combination of ruthenium, molybdenum, and tungsten; conformally depositing a barrier layer over the intermediate structure such that the barrier layer covers the sidewalls of the graphene layer in the recesses; and anisotropically etching the metal layer via the recesses, where an etching gas for the anisotropic etching contains oxygen, and where the barrier layer includes a barrier material that etches slower than the metal layer in the anisotropic etching using the etching gas containing oxygen.

Example 13. The method of example 12, further comprising sequentially repeating the depositing of the barrier layer and the etching of the metal layer until the recesses open to the substrate.

Example 14. The method of examples 12 and 13, further comprising removing the barrier layer after the recesses are open to the substrate.

Example 15. The method of examples 12 to 14, further comprising: forming another graphene layer on exposed portions of patterned features of the metal layer; and depositing a dielectric material between the patterned features of the metal layer.

Example 16. The method of examples 12 and 13, where the metal layer contains ruthenium, where the barrier layer contains silicon nitride, and where the graphene layer remains covered by the barrier layer during the etching of the metal layer.

Example 17. The method of examples 12 and 13, where patterned feature widths of the graphene layer remain constant during the etching of the metal layer.

Example 18. The method of example 12, where the graphene layer has a thickness range of 1 nm to 10 nm.

Example 19. A method for making a semiconductor device, the method comprising: forming a metal layer over a substrate, where the metal layer contains one of or any combination of ruthenium, molybdenum, and tungsten; forming a first graphene layer over the metal layer; forming a first mask layer over the metal layer; forming a second mask layer over the first mask layer; patterning and etching the second mask layer to form recesses in the second mask layer; patterning and etching the first mask layer to extend the recesses through the first mask layer; patterning and etching the first graphene layer to extend the recesses through the first graphene layer to form an intermediate structure; conformally depositing a barrier layer over the intermediate structure such that the barrier layer covers sidewalls of the first graphene layer in the recesses; anisotropically etching the metal layer to extend the recesses in the metal layer, where an etching gas for the anisotropic etching contains oxygen, where the barrier layer includes a barrier material such the metal layer selectively etched relative to the barrier layer in the anisotropic etching using the etching gas containing oxygen, and where the sidewalls of the first graphene layer remain covered by the barrier layer during the etching of the metal layer; and sequentially repeating the depositing of the barrier layer and the etching of the metal layer until the recesses open to the substrate.

Example 20. The method of example 19, further comprising: removing at least part of the barrier layer after the recesses are open to the substrate; forming a second graphene layer on exposed portions of patterned features of the metal layer; and depositing a dielectric material between the patterned features of the metal layer.

While illustrative and example embodiments have been described with reference to illustrative drawings, this description is not intended to be construed in a limiting sense. Various modifications and combinations of the illustrative and example embodiments, as well as other embodiments, can be apparent to persons skilled in the pertinent art upon referencing the present disclosure. It is therefore intended that the appended claims encompass any and all of such modifications, equivalents, or embodiments.

What is claimed is:

1. A method for making a semiconductor device, the method comprising:
providing an intermediate structure comprising a substrate, a metal layer, a graphene layer, and a mask layer, wherein the metal layer is over the substrate, wherein the graphene layer is over the metal layer, wherein the mask layer is over the graphene layer, and wherein the mask layer and the graphene layer are patterned and etched with recesses opening to a top surface of the metal layer such that sidewalls of the graphene layer are exposed in the recesses;
conformally depositing a barrier layer over the intermediate structure such that the barrier layer covers the sidewalls of the graphene layer in the recesses; and
anisotropically etching the metal layer via the recesses.

2. The method of claim 1, further comprising sequentially repeating the depositing of the barrier layer and the etching of the metal layer until the recesses open to the substrate.

3. The method of claim 2, further comprising removing the barrier layer after the recesses are open to the substrate.

4. The method of claim 3, further comprising:
forming another graphene layer on exposed portions of patterned features of the metal layer; and
depositing a dielectric material between the patterned features of the metal layer.

5. The method of claim 1, wherein the metal layer contains ruthenium, wherein the barrier layer contains silicon and nitrogen, and wherein an etching gas for the anisotropic etching contains oxygen.

6. The method of claim 5, wherein the mask layer comprises a first mask layer including an oxide-containing material, and a second mask layer including silicon nitride.

7. The method of claim 1, wherein patterned feature widths of the graphene layer remain constant during the etching of the metal layer.

8. The method of claim 1, wherein the graphene layer remains covered by the barrier layer during the etching of the metal layer.

9. The method of claim 1, wherein the graphene layer has a thickness range of 1 nm to 10 nm.

10. The method of claim 1, wherein the barrier layer is silicon nitride, and wherein the depositing of the barrier layer includes an atomic layer deposition.

11. The method of claim 1, wherein the metal layer contains one of or any combination of ruthenium, molybdenum, and tungsten; wherein an etching gas for the anisotropic etching contains oxygen; and wherein the barrier layer includes a barrier material that etches slower than the metal layer in the anisotropic etching using the etching gas containing oxygen.

12. A method for making a semiconductor device, the method comprising:
providing an intermediate structure comprising a substrate, a metal layer, a graphene layer, and a mask layer, wherein the metal layer is over the substrate, wherein the graphene layer is over the metal layer, wherein the mask layer is over the graphene layer, and wherein the mask layer and the graphene layer are patterned and etched with recesses opening to a top surface of the metal layer such that sidewalls of the graphene layer are exposed in the recesses, wherein the metal layer contains one of or any combination of ruthenium, molybdenum, and tungsten;
conformally depositing a barrier layer over the intermediate structure such that the barrier layer covers the sidewalls of the graphene layer in the recesses; and
anisotropically etching the metal layer via the recesses, wherein an etching gas for the anisotropic etching contains oxygen, and wherein the barrier layer includes a barrier material that etches slower than the metal layer in the anisotropic etching using the etching gas containing oxygen.

13. The method of claim 12, further comprising sequentially repeating the depositing of the barrier layer and the etching of the metal layer until the recesses open to the substrate.

14. The method of claim 13, further comprising removing the barrier layer after the recesses are open to the substrate.

15. The method of claim 14, further comprising:
forming another graphene layer on exposed portions of patterned features of the metal layer; and
depositing a dielectric material between the patterned features of the metal layer.

16. The method of claim 13, wherein the metal layer contains ruthenium, wherein the barrier layer contains silicon nitride, and wherein the graphene layer remains covered by the barrier layer during the etching of the metal layer.

17. The method of claim 13, wherein patterned feature widths of the graphene layer remain constant during the etching of the metal layer.

18. The method of claim 12, wherein the graphene layer has a thickness range of 1 nm to 10 nm.

19. A method for making a semiconductor device, the method comprising:
forming a metal layer over a substrate, wherein the metal layer contains one of or any combination of ruthenium, molybdenum, and tungsten;
forming a first graphene layer over the metal layer;
forming a first mask layer over the metal layer;
forming a second mask layer over the first mask layer;
patterning and etching the second mask layer to form recesses in the second mask layer;
patterning and etching the first mask layer to extend the recesses through the first mask layer;
patterning and etching the first graphene layer to extend the recesses through the first graphene layer to form an intermediate structure;
conformally depositing a barrier layer over the intermediate structure such that the barrier layer covers sidewalls of the first graphene layer in the recesses;
anisotropically etching the metal layer to extend the recesses in the metal layer, wherein an etching gas for the anisotropic etching contains oxygen, wherein the barrier layer includes a barrier material such the metal layer selectively etched relative to the barrier layer in the anisotropic etching using the etching gas containing oxygen, and wherein the sidewalls of the first graphene layer remain covered by the barrier layer during the etching of the metal layer; and
sequentially repeating the depositing of the barrier layer and the etching of the metal layer until the recesses open to the substrate.

20. The method of claim 19, further comprising:
removing at least part of the barrier layer after the recesses are open to the substrate;
forming a second graphene layer on exposed portions of patterned features of the metal layer; and
depositing a dielectric material between the patterned features of the metal layer.
